(19) United States
(12) Patent Application Publication
(10) Pub. No.: US 2024/0405068 A1
(43) Pub. Date: Dec. 5, 2024

(54) Semiconductor Device and Method of Forming MEMS Super-Junction Metal Oxide Semiconductor Using Epitaxial Layer

(71) Applicant: IceMos Technology Limited, Belfast (GB)

(72) Inventors: Samuel J. Anderson, Tempe, AZ (US); Takeshi Ishiguro, Fukushima (JP)

(73) Assignee: IceMos Technology Limited, Belfast (GB)

(21) Appl. No.: 18/622,990

(22) Filed: Mar. 31, 2024

Related U.S. Application Data
(60) Provisional application No. 63/506,267, filed on Jun. 5, 2023.
(60) Provisional application No. 63/506,430, filed on Jun. 6, 2023.

(51) Int. Cl. H01L 29/06; H01L 21/02; H01L 21/225; H01L 21/268; H01L 21/3065; H01L 29/66; H01L 29/78; H02M 3/335

(52) U.S. Cl. CPC H01L 29/0634; H01L 21/02227; H01L 21/2254; H01L 21/268; H01L 21/3065; H01L 29/66734; H01L 29/7813; H02M 3/33523

(57) ABSTRACT

A semiconductor device has a substrate and semiconductor layer formed over the substrate. The semiconductor layer has a first conductivity type. A trench is formed through the semiconductor layer. An epitaxial layer having a second conductivity type is formed over a surface of the semiconductor layer and a side surface of the trench. The epitaxial layer is diffused into the semiconductor layer to form a first column of semiconductor material having the second conductivity type within the semiconductor layer. A first insulating layer is formed over the side surface of the trench. A body region is formed within the semiconductor layer. A source region is formed within the body region. A gate region is formed within the body region. A second insulating layer is formed over the trench. A third insulating layer is formed over the second insulating layer. A conductive layer is formed over the third insulating layer.

### CLAIM TO DOMESTIC PRIORITY

The present application claims the benefit of U.S. Provisional Application No. 63/506,267, filed Jun. 5, 2023, which application is incorporated herein by reference. The present application further claims the benefit of U.S. Provisional Application No. 63/506,430, filed Jun. 5, 2023, which application is incorporated herein by reference.

### FIELD OF THE INVENTION

The present invention relates in general to a semiconductor device and, more particularly, to a semiconductor device and method of forming a MEMS super-junction MOSFET using an epitaxial layer to optimize for R_{DSON}.

### BACKGROUND OF THE INVENTION

Semiconductor devices are commonly found in modern electrical products. Semiconductor devices vary in the number and density of electrical components. Discrete semiconductor devices generally contain one type of electrical component, e.g., a light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, interface circuits, and other signal processing circuits.

With respect to the power MOSFET, such devices have been made with a super-junction structure. Advances have been made to merge micro-electrical-mechanical system (MEMS) layer transfer and super-junction technology. Super-junction has been an important development for power devices since the introduction of the insulated gate bipolar transistor (IGBT) in the 1980s. Super-junction has extended the well-known theoretical study on the limit of silicon in high-voltage devices. Super-junction involves a deep trench between the cells and a p type column of semiconductor material lining the sidewall of the trenches. MEMS super-junction reduces manufacturing cost by merging MEMS processing techniques into CMOS processes to build super-junction metal oxide semiconductor (SJMOS) structures. A MEMS SJMOS is referred to as mSJMOS.

Super-junction can be challenging to realize in practice, due to the requirement of forming three-dimensional device structures with a high aspect ratio. SJMOS addresses the super-junction manufacturing and cost problem through a low-cost, commercially viable MEMS layer transfer and deep reactive ion etch fabrication technology. The comparison between multiple-epi and the merger of MEMS based SJMOS devices is differentiated by the number of mask layers. There can be twenty or more mask layers used in the manufacture of multi-epi, while SJMOS uses nine mask layers.

Semiconductor devices perform a wide range of functions, such as signal processing, high-speed calculations, transmitting and receiving electromagnetic signals, controlling electrical devices, transforming sunlight to electricity, and creating visual projections for television displays. Semiconductor devices are found in the fields of communications, power conversion, networks, computers, and consumer products. Semiconductor devices are also found in military applications, aerospace, aviation, automotive, data processing centers, industrial controllers, and office equipment.

MOSFETs are commonly used in electrical circuits, such as communication systems and power supplies. Power MOSFETs are particularly useful when used as electric switches to enable and disable the conduction of relatively large currents. The on/off state of the power MOSFET is controlled by applying and removing a triggering signal at the gate electrode. When turned on, the electric current in the MOSFET flows between the drain and source. When turned off, the electric current is blocked by the MOSFET.

Power MOSFETs are typically arranged in an array of thousands of individual MOSFET cells electrically connected in parallel. The MOSFET cell has an inherent drain-source resistance (R_{DSON}) in the conducting state. The width of the MOSFET cell influences the electrical resistance of the MOSFET cell. The larger the cell width, the larger the resistance. Conversely, the larger the cell density with corresponding smaller cell width, the smaller the resistance. Many applications, such as portable electrical devices, require a low operating voltage, e.g., less than 5 VDC. The low voltage electrical equipment in the portable electrical devices creates a demand for power supplies that can deliver the requisite operating potential.

To combine the benefits of deep super-junction trenches with high cell density, a process of doping the sidewalls of the trenches to a depth of 50-100 micrometers (μm), given a trench width of less than 3.0 μm, is needed. Angled ion implantation has limited depth with narrow trenches and small cell pitch. For example, a 4.0 degree angled ion implantation can reach only 40-50 μm with a 3.0 micrometers (μm) trench. To increase cell density and reduce R_{DSON} for the power MOSFET, the trench width must become smaller, and doping must reach deeper, which exceeds the capability of the angled ion implantation method.

### BRIEF DESCRIPTION OF THE DRAWINGS

FIG. 1 illustrates a block diagram of a power supply and electrical equipment;

FIG. 2 is a schematic and block diagram of a pulse width modulated power supply;

FIG. 3 illustrates a semiconductor wafer with a plurality of semiconductor die;

FIGS. 4a-4t illustrate a process of forming a multi-cell MEMS super-junction MOSFET using vapor phase deposition to optimize for R_{DSON};

FIG. 5 illustrates the multi-cell MEMS super-junction MOSFET from FIGS. 4a-4t;

FIGS. 6a-6h illustrate another process of forming a multi-cell MEMS super-junction MOSFET using vapor phase deposition to optimize for R_{DSON};

FIGS. 7a-7g illustrate a process of forming a multi-cell MEMS super-junction MOSFET using epi doping; and

FIGS. 8a-8e illustrate an atomic level deposition of p dopant to form the epi doping.

### DETAILED DESCRIPTION OF THE DRAWINGS

The present invention is described in one or more embodiments in the following description with reference to the figures. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Most modern electrical equipment requires a power supply to provide a DC operating potential to the electrical components contained therein. Common types of electrical equipment which use power supplies include aerospace, personal computers, energy systems, telecommunication systems, audio-video equipment, consumer electrical devices, automotive components, portable electrical devices, data processing centers, LED lighting, electric vehicles, and other devices which utilize integrated circuits, semiconductor chips, or otherwise require DC operating potential. Many semiconductor components require a low voltage DC operating potential. However, many sources of electric power are AC, or high voltage DC, which must be converted to low voltage DC for the electrical equipment.

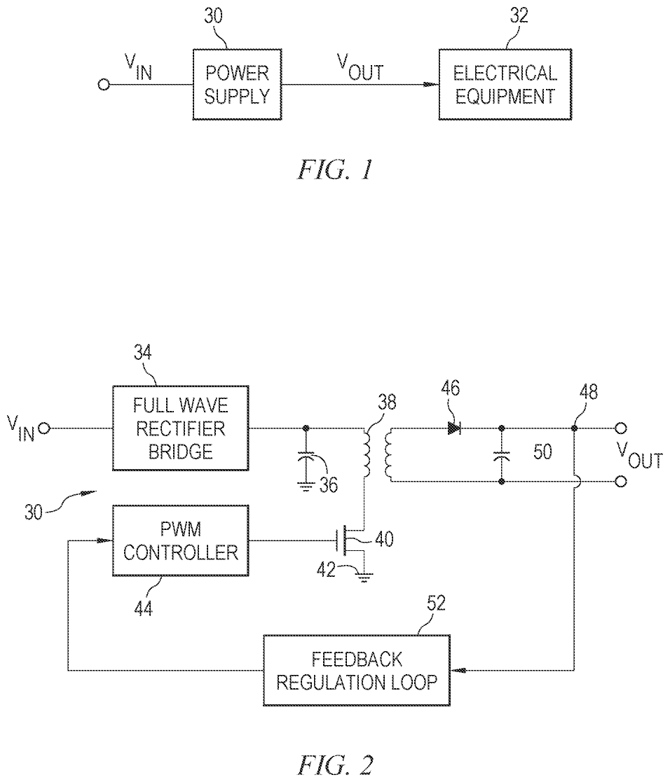

In one common arrangement, the AC/DC power supply receives an AC input voltage, e.g., between 110 and 240 VAC, and converts the AC input voltage to the DC operating voltage. Referring to FIG. 1, a PWM power supply 30 is shown providing a DC operating potential to electrical equipment 32. Power supply 30 receives input voltage V_{IN} and produces one or more DC output voltages. The electrical equipment 32 may take the form of aerospace equipment, personal computers, energy systems, telecommunication systems, audio-video equipment, consumer electrical devices, automotive components, portable electrical devices, aerospace, data processing centers, LED lighting, charging stations for electric vehicles, variable speed drives for electric motors, and other devices which utilize integrated circuits, semiconductor chips, or otherwise require DC operating potential from the power supply.

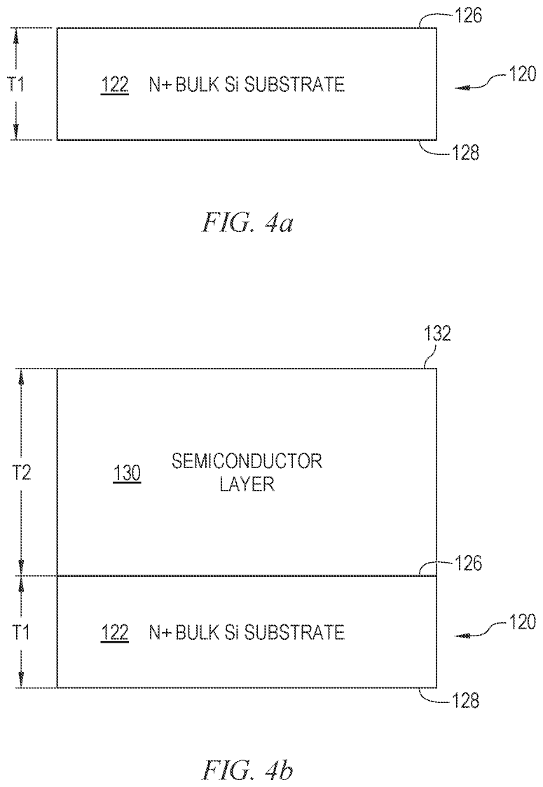

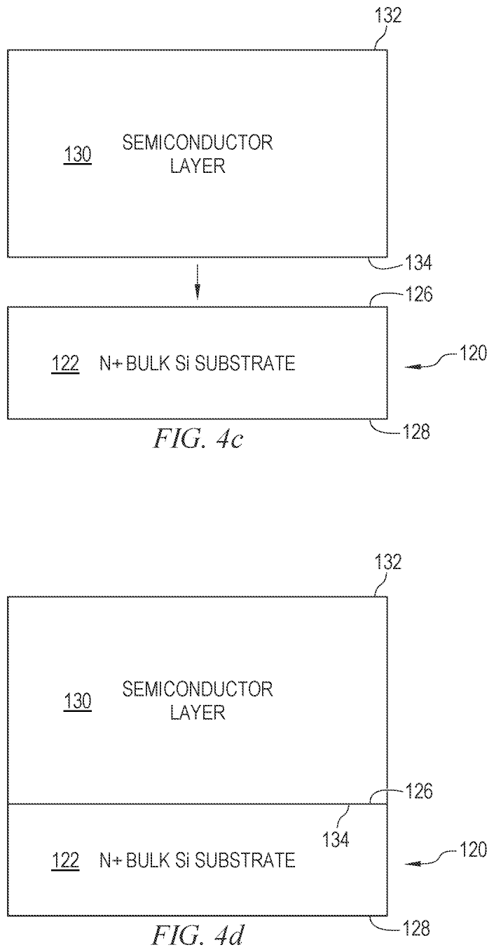

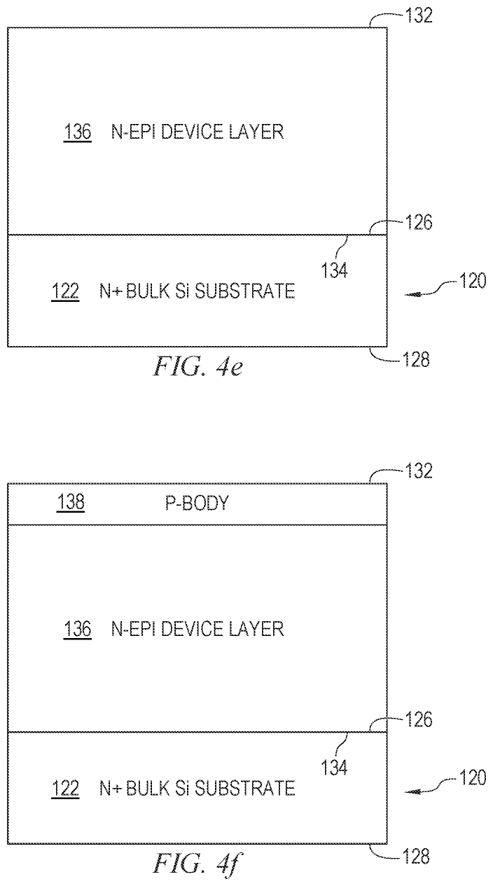

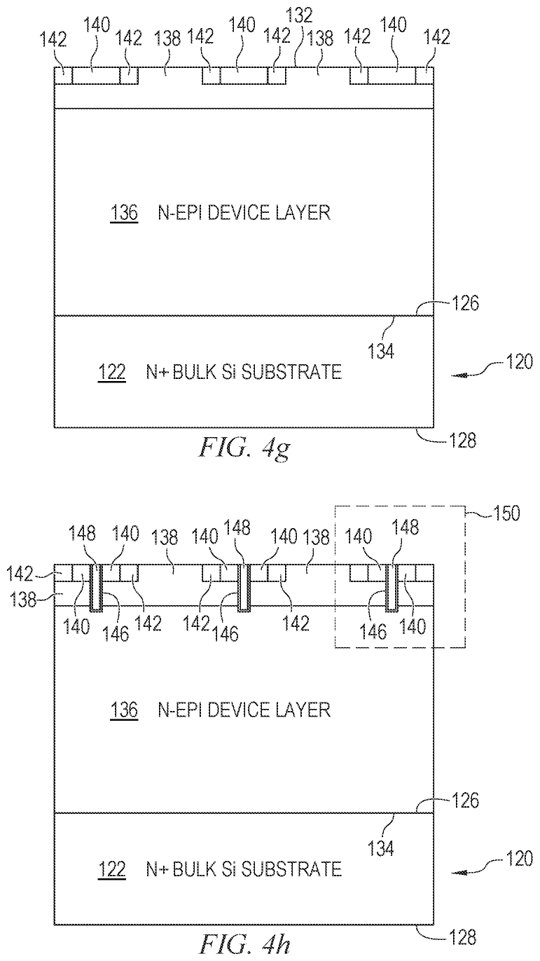

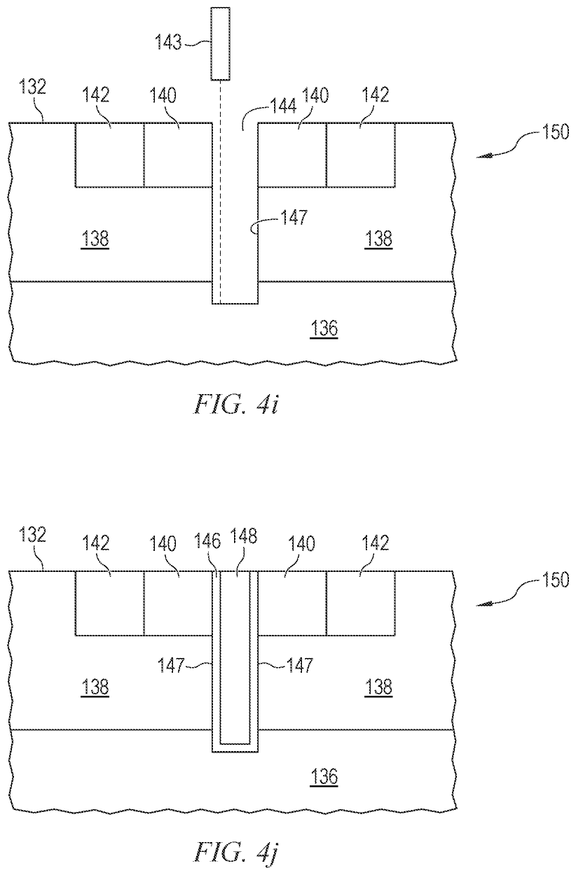

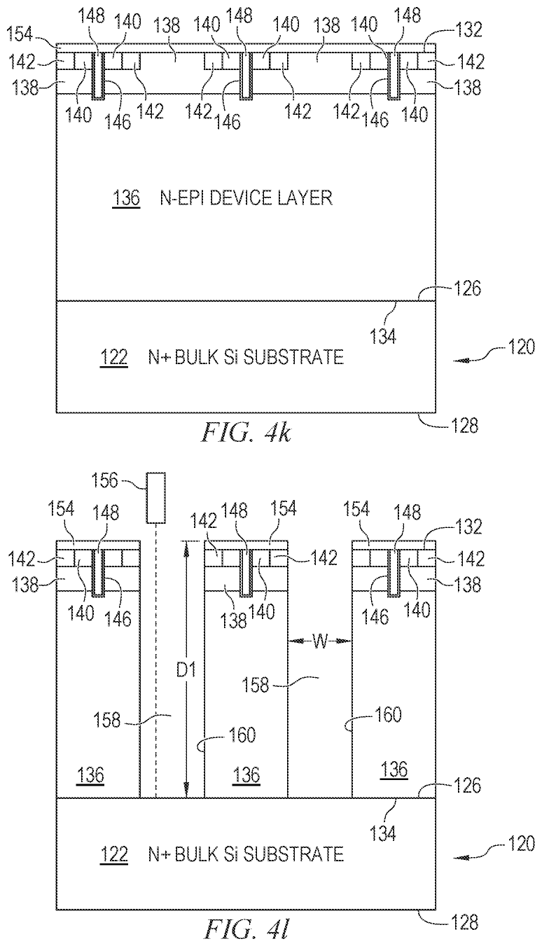

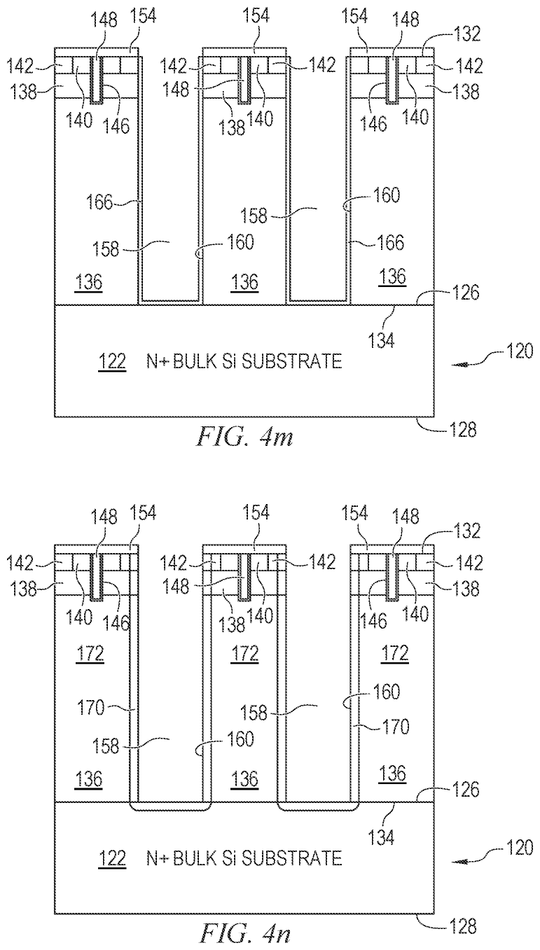

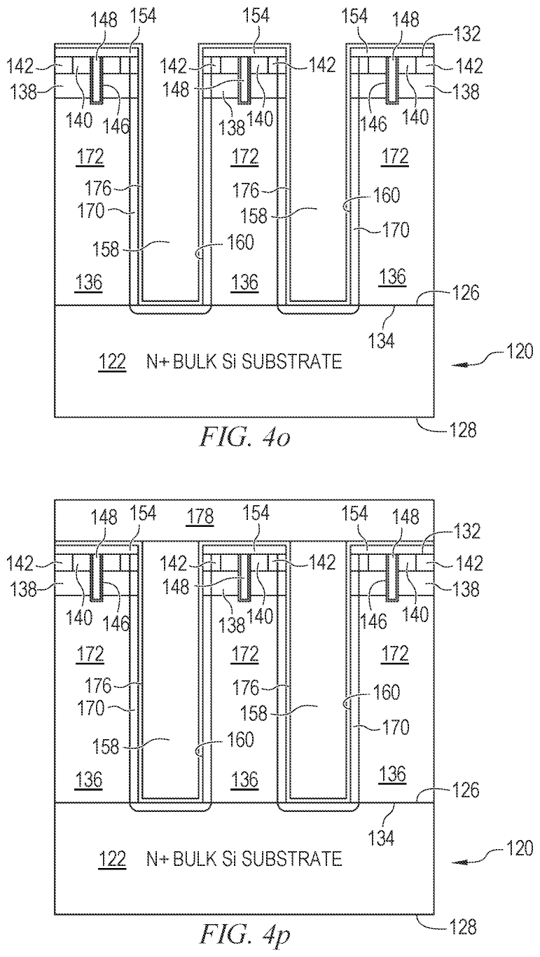

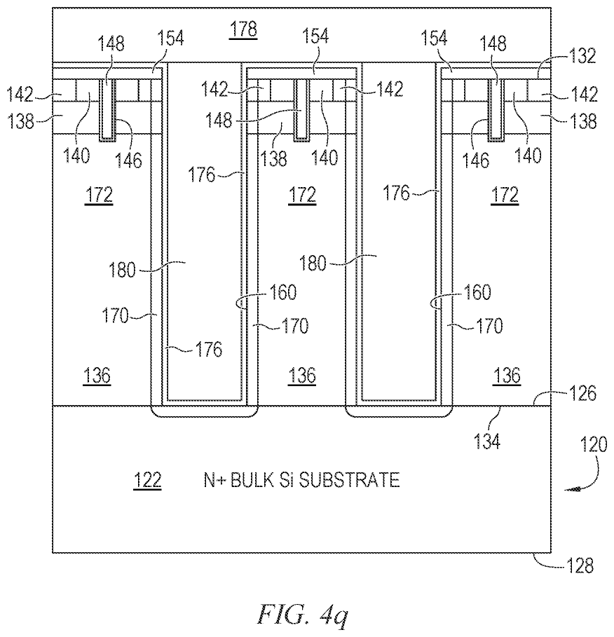

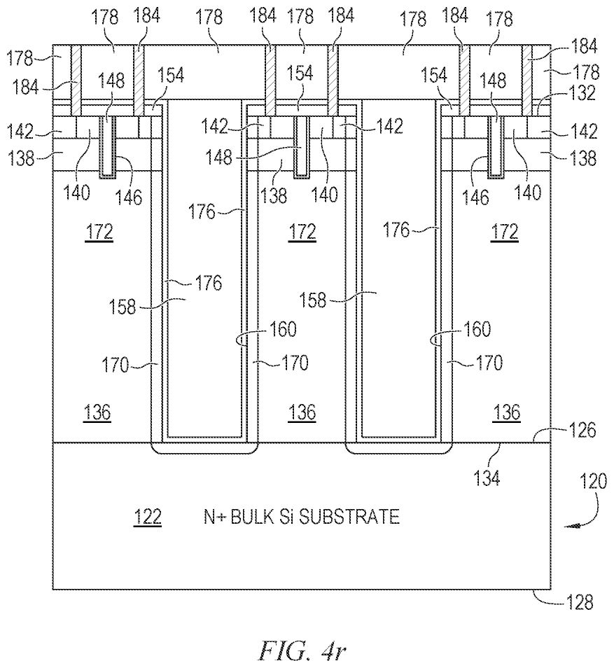

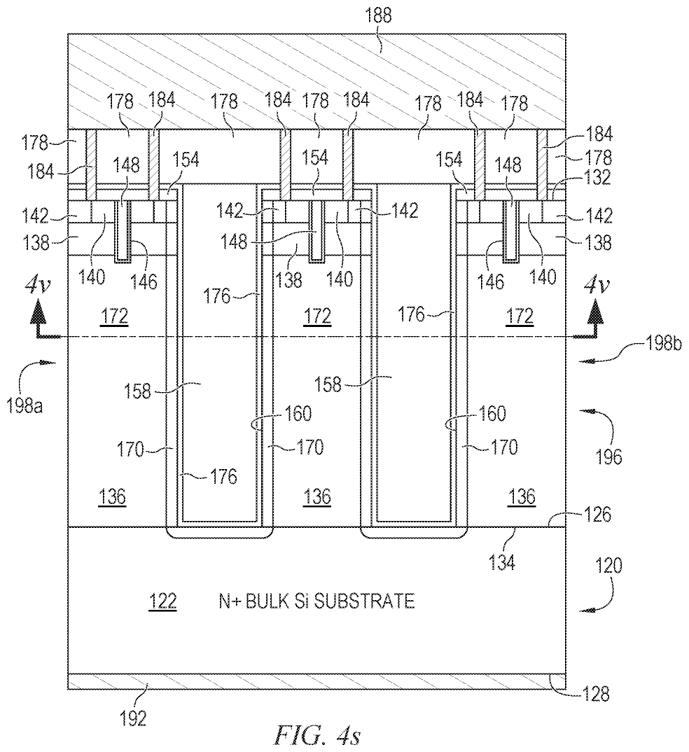

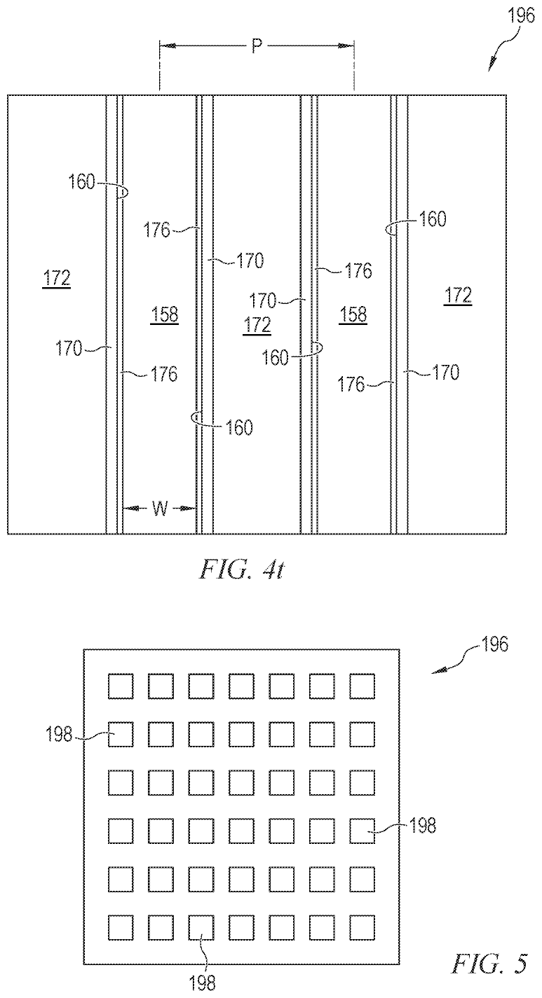

Further detail of PWM power supply 30 is shown in FIG. 2. The input voltage V_{IN} may be an AC signal, e.g., 110 VAC, or DC signal, e.g., 48 volts. For the case of an AC input voltage, power supply 30 has a full-wave rectifier bridge 34. The full-wave rectifier bridge 34 converts the AC input voltage to a DC voltage. In the case of a DC input voltage, the full-wave rectifier bridge 34 is omitted. Capacitor 36 smooths and filters the DC voltage. The DC voltage is applied to a primary winding or inductor of transformer 38. The primary winding of transformer 38 is also coupled through power transistor 40 to ground terminal 42. In one embodiment, power transistor 40 is a multi-cell vertical power MOSFET, as described in FIGS. 4a-4t, 6a-6h, and 7a-7g. The gate of MOSFET 40 receives a PWM control signal from PWM controller 44. The secondary winding of transformer 38 is coupled to rectifier diode 46 to create the DC output voltage V_{OUT} of power supply 30 at node 48. Capacitor 50 filters the DC output voltage V_{OUT}. The DC output voltage V_{OUT} is routed back through feedback regulation loop 52 to a control input of PWM controller 44. The DC output voltage V_{OUT} generates the feedback signal which PWM controller 44 uses to regulate the power conversion process and maintain a relatively constant output voltage V_{OUT} under changing loads. The aforedescribed electrical components of the power supply module are typically mounted to and electrically interconnected through a printed circuit board.

In the power conversion process, PWM controller 44 sets the conduction time duty cycle of MOSFET 40 to store energy in the primary winding of transformer 38 and then transfer the stored energy to the secondary winding during the off-time of MOSFET 40. The output voltage V_{OUT} is determined by the energy transfer between the primary winding and secondary winding of transformer 38. The energy transfer is regulated by PWM controller 44 via the duty cycle of the PWM control signal to MOSFET 40. Feedback regulation loop 52 generates the feedback signal to PWM controller 44 in response to the output voltage V_{OUT} to set the conduction time duty cycle of MOSFET 40.

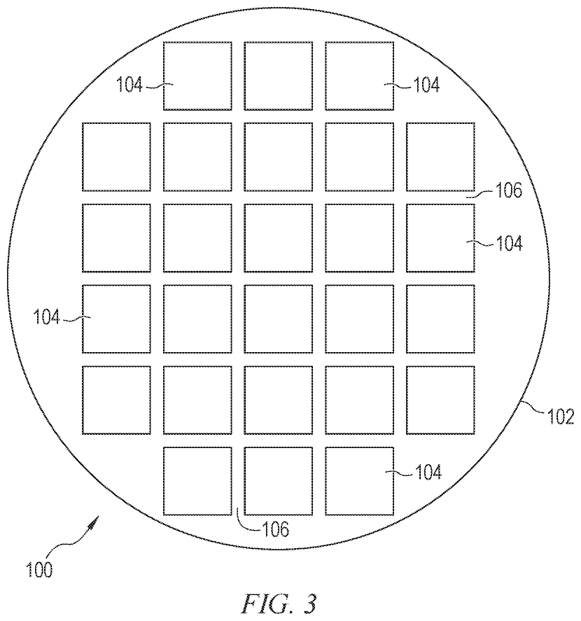

FIG. 3 shows semiconductor wafer or substrate 100 with a base substrate material 102, such as silicon (Si), SiC, cubic silicon carbide (3C-SiC), germanium, aluminum phosphide, aluminum arsenide, gallium arsenide, gallium nitride, indium phosphide, diamond, and all families of III-V and II-VI semiconductor materials for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

Semiconductor die 104 can be a vertical or lateral power MOSFET with gate and source terminals on a first surface of the die and drain terminal on a second surface opposite the first surface of the die. Semiconductor die 104 can be contained in a semiconductor package, such as TO220, T0247, decawat package (DPAK), double decawat package (D2PAK), TSON, micro leadframe package (MLP), dual flat no-leads (DEN), and other packages for vertical discrete devices or lateral chip scale up-drain packages. In the present embodiment, semiconductor die 104 contains a power MOSFET, applicable to MOSFET 40, with enhanced features to optimize resistance.

FIGS. 4a-4t illustrate a process of forming a multi-cell MEMS super-junction MOSFET using vapor phase deposition to optimize for R_{DSON}. FIG. 4a illustrates substrate 120 containing a base semiconductor material 122, such as Si, SiC, 3C-SiC, germanium, aluminum phosphide, aluminum arsenide, gallium arsenide, gallium nitride, indium phosphide, diamond, and all families of III-V and II-VI semiconductor materials for structural support. In one embodiment, substrate 120 contains N+ bulk Si with a thickness T1 of about 500-700 μm. Substrate 120 includes a first surface 126 and second surface 128 opposite the first surface 126.

FIGS. 4b-4t represent a portion of substrate 120 showing formation of two cells of the mSJMOS or MOSFET. In FIG. 4b, semiconductor layer 130 with surface 132 is epitaxially grown over surface 126 of substrate 120. Thickness T2 is determined by the voltage rating with thicker epi required for a higher voltage. In super-junction technology, epi thickness or the length of the drift region is substantially proportional to the breakdown voltage. For example, T2 can be 45.0 μm for 600V and 100.0 μm for 1200V.

Alternatively, semiconductor layer 130 is joined to substrate 120 using a high temperature anneal, fusion bonding, plasma activated direct wafer bonding (DWB), or other DWB process. In FIG. 4c, semiconductor layer 130 is disposed over surface 126 of substrate 120. Surface 134 of semiconductor layer 130 and surface 126 of substrate 120 are planarized, polished, and cleaned to be flat and smooth, prior to bonding. The lattice structures of semiconductor layer 130 and substrate 120 can be aligned to optimize adhesion. Water molecules can be applied to surfaces 126 and 134 to aid in the bonding process. Surface 134 of semiconductor layer 130 is brought into contact with surface 126 of substrate 120. DWB is accomplished with chemical bonds and intermolecular interactions at temperature, including van der Waals forces, hydrogen bonds, and covalent bonds, between surface 134 and surface 126. DWB temperatures range from ambient to 100's° C. FIG. 4d shows semiconductor layer 130 direct wafer bonded to surface 126 of substrate 120.

In FIG. 4e, semiconductor layer 130 from FIG. 4b or 4d is doped to change the physical and electrical characteristics of the layer. Doping is the intentional introduction of impurities (dopant) into the lattice structure of an intrinsic semiconductor material (equal numbers of free electrons and holes) for the purpose of modulating its electrical, optical, physical, and structural properties. The doped material becomes an extrinsic semiconductor material. The doping is said to be low or light, given one dopant atom per 100 million (1e8) atoms, or 5e14 dopant atoms/cm³. The doping is referred to as high or heavy, given one dopant atom per ten thousand (1e4) atoms, or 5e18 dopant atoms/cm³. The dopant can be n-type material or p-type material, depending on the type of semiconductor device being made. The mSJMOS can be an n-channel device (N-MOS) or a p-channel device (P-MOS), where “p” denotes a positive carrier type (hole) and “n” denotes a negative carrier type (electron). Although the present embodiment is described in terms of an N-MOS device, the opposite type semiconductor material can be used to form a P-MOS device.

In various implantation and diffusion steps described herein, the doping is performed by an initial ion implantation, solid diffusion, liquid diffusion, drive-in diffusion, spin-on deposits, plasma doping, vapor phase doping, laser doping, or the like to deposit impurities into the lattice structure of the region or layer. Doping with boron (B), aluminum (Al), or gallium (Ga) results in a more p-type region, and doping with phosphorus (P), antimony (Sb), or arsenic (As) impurities results in a n-type region. Other dopants may be utilized, such as bismuth (Bi) and indium (In), depending on the material of the substrate and the desired strength of the doping. First, the impurity is implanted in the surface of the intrinsic material, e.g., by ion implantation. After implantation of impurities at the surface, a drive-in diffusion step is typically required to disperse or distribute the impurities throughout the lattice structure of the layer or region. For example, following implantation of the dopant, a drive-in step at a temperature of 1200° C. for up to 12 hours. To minimize repetitive text, doping or doped refers to both the initial implanting of impurities and driving in or distributing the impurities to the lattice structure.

N doping concentration is determined by voltage rating. N doping concentration is also determined for edge termination. N-epi thickness is determined by the drift length. In one embodiment, semiconductor layer 130 is doped with n-type impurities, e.g., P, Sb, or As at 1e16 atoms/cm³ for 30V and about 1e14 atoms/cm³ for 600V, to form an N-epi device layer 136 with a thickness dependent on design breakdown voltage. For example, the epi thickness is 1.5-2.0 μm for 30V and 4.0 μm for 60V. mSJMOS 196 will be formed in part in N-epi device layer 136.

In FIG. 4f, surface 132 is implanted with a p-type impurity, such as B, Al, or Ga. The implant is performed at an energy level of about 30-200 kilo-electron-volts (KeV) with a dose between 1e16 and 1e18 atoms/cm³, preferably 4e17 atoms/cm³. The p-type impurities are driven-in, at a temperature of 900° C. for 10-30 minutes, to form p body 138.

In FIG. 4g, surface 132 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form n+ source region 140.

Surface 132 is further implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form p+ contact 142.

In FIGS. 4h-4j, a portion of n+ source region 140, p body 138, and N-epitaxial (epi) device layer 136 is removed by an etching process or laser direct ablation (LDA) using laser 143 to form trench 144 extending into the N-epi device layer. FIGS. 4i-4j show further detail of box 150 from FIG. 4h. An insulating layer 146 is formed over surface 147 within trench 144. Insulating layers, as described herein, can be silicon dioxide (SiO2), silicon nitride (Si3N4), silicon oxynitride (SiON), tantalum pentoxide (Ta2O5), aluminum oxide (Al2O3), polyimide, benzocyclobutene (BCB), polybenzoxazoles (PBO), or other suitable insulating or dielectric material formed using PVD, CVD, screen printing, spin coating, spray coating, sintering, or thermal oxidation. In one embodiment, insulating layer 146 is an oxide layer. Polysilicon material 148 is formed over insulating layer 146 within trench 144. Polysilicon material 148 can be formed by PVD, CVD, screen printing, spin coating, spray coating, or other suitable deposition process. Polysilicon material 148 operates as a gate field plate. Note that n+ source region 140 and p+ contact 142 can be formed after trench 144, insulating layer 146, and polysilicon material 148.

In FIG. 4k, an insulating layer 154 is formed over surface 132. In FIG. 4l, a portion of insulating layer 154, p body 138, and N-epi device layer 136 is removed by DRIE or LDA using laser 156 to form trench 158. Trench 158 includes substantially vertical side surfaces 160. Trench 158 must extend at least to surface 126, and in most cases, will extend past surface 126 into substrate material 122. In the case of trench etching, trenches 158 can be formed by deep reactive ion etching (DRIE) with a width W of 1.0-2.0 or less μm, preferably 0.5 μm, and depth D1 of 1.5-2.0 μm for 30V and 100.0 μm for 1200V, depending on epi thickness, to extend past surface 126 into substrate material 122. The width W of trench 158 is made small to decrease cell pitch and increase cell density. Depth D1 is greater for higher voltages and thicker epi. The DRIE is a highly anisotropic etch process used to create deep penetration, steep-sided holes, cavities, and trenches in wafers/substrates, typically with high aspect ratios. DRIE utilizes an ionized gas or plasma, such as sulfur hexafluoride (SF₆), to remove material from N-epi device layer 136 and semiconductor material 122. DRIE technology permits deeper trenches 158 with straighter side surfaces 160. To create deep anisotropic etching of silicon, the etch process switches between different plasma chemistries to provide fluorine-based etching of the silicon while protecting the side surface of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 158. Alternatively, trenches 158 can be formed by plasma etching, reactive ion etching (RIE), sputter etching, vapor phase etching, and chemical etching. A first mask (not shown) is typically formed over surface 132 to isolate trenches 158 during the etching process.

The side surfaces 160 of each trench 158 can be smoothed using an isotropic plasma etch and may be used to remove a thin layer of silicon, e.g., 100-1000 A from the trench sidewalls. Alternatively, a sacrificial thermal oxide or silicon dioxide layer can be grown on sidewall surfaces 160 of trenches 158. The sacrificial thermal oxide is then removed using an etch, such as a buffered oxide etch, or a diluted hydrofluoric (HF) acid etch, or other wet chemistry followed by HF vapor phase fuming, to smooth the inner wall. Another sacrificial thermal oxide layer is again grown on side surfaces 160 of trenches 158. The sacrificial thermal oxide layer is again removed by wet chemistry following by HF vapor phase fuming to smooth the inner wall. The process of repetitive growth of thermal oxide and removal continues multiple times until side surface 160 of trench 158 is smooth. By eliminating the scalloping from the DRIE etch and using the sacrificial thermal oxide layer followed by HF fuming or any oxide and silicon etches, side surface 160 can be smoothed to a tapered form. The use of the smoothing techniques can produce smooth trench surfaces with rounded corners while removing residual stress and unwanted contaminates.

In FIG. 4m, thin film 166 is deposited on side surfaces 160 of trenches 158 using vapor phase deposition or plasma doping. Thin film 166 contains p-type dopant, such as boron, aluminum, or gallium impurities. In one embodiment, p type thin film 166 is deposited by low temperature CVD, PVD, and/or plasma enhanced chemical vapor deposition (PECVD). In FIG. 4n, p type thin film 166 is then diffused into N-epi device layer 136 by application of pressure and heat, e.g., in a reaction chamber, in the range of 800-1000° C. at atmospheric pressure. Alternatively, the impurity atoms are transported from the vapor source onto surface 160 of trench 158 and simultaneously diffused into the semiconductor wafer, again by application of heat and pressure in a reaction chamber. The vapor source maintains a constant level of surface concentration during the entire diffusion period. The diffusion forms p regions or columns 170, leaving n regions or columns 172 from N-epi device layer 136 between the p columns. That is, forming p column 170 retains a portion of N-epi device layer 136 as n column 172 adjacent to the p column. In one embodiment, p columns 170 have a width of 0.1-0.5 μm. Accordingly, p columns 170 are formed by vapor phase deposition or plasma doping and diffusion, and n columns 172 are the remaining N-epi device layer 136 between the p columns. The vapor phase deposition or plasma doping and diffusion is particularly useful to form p columns 170, given the narrow trenches 158, e.g., 0.5 μm or less.

In FIG. 4o, insulating layer 176 is formed over insulating layer 154 and into trench 158 over a side surface of p columns 170. Insulating layer 176 can be SiO2, Si3N4, SiON, Ta2O5, Al203, polyimide, BCB, PBO, or other suitable insulating or dielectric material formed using PVD, CVD, screen printing, spin coating, spray coating, sintering, or thermal oxidation. Insulating layer 176 typically, although not necessarily, covers the bottom of trench 158.

In FIG. 4p, insulating layer or material 178 is formed over insulating layer 176 and trench 158. Insulating material 178 can be SiO2, Si3N4, SiON, Ta205, Al203, polyimide, BCB, PBO, or other suitable insulating or dielectric material. In one embodiment, insulating layer 178 is formed using a MEMS layer transfer or layer bonding process to form a cap over trench 158, as it is not necessary to completely fill the trenches with insulating material. As part of MEMS layer transfer, insulating layer or cap 178, as an entire wafer, can be direct wafer bonded to insulating layer 176 to cover trench 158.

In another embodiment, insulating layer or material 180 is formed within trench 158, as shown in FIG. 4q. Insulating material 180 can be SiO2, Si3N4, SiON, Ta205, Al203, polyimide, BCB, PBO, or other suitable insulating or dielectric material formed using PVD, CVD, screen printing, spin coating, spray coating, sintering, or thermal oxidation. In one embodiment, insulating layer 180 is formed using a MEMS layer transfer or layer bonding process, as described above.

Insulating material 178 can also be formed to cap trenches 158 using other techniques, such as LPCVD, TEOS, or other suitable oxide deposition process. Insulating material 178 can be polysilicon, re-crystallized polysilicon, single crystal silicon, or semi-insulating polycrystalline silicon (SIPOS). In one embodiment, insulating material 178 is SIPOS deposited into trenches 158 using a spun-on-glass (SOG) technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

Continuing from FIG. 4p, a portion of insulating layer 178 is removed by an etching process or LDA to form vias through the insulating layer extending to n+ source region 140, as in FIG. 4r. The vias are filled with conductive material to form conductive vias 184. Conductive vias 184 can be one or more layers of aluminum (Al), copper (Cu), tin (Sn), nickel (Ni), gold (Au), silver (Ag), tungsten (W), or other suitable electrically conductive material formed using patterning with PVD, CVD, sputtering, electrolytic plating, electroless plating process, or other suitable metal deposition process. Conductive vias 184 make electrical contact with n+ source region 140. Conductive vias 184 are also used to generate an electric field for polysilicon gate material 148 (not shown).

In FIG. 4s, one or more electrically conductive layers 188 is formed over insulating layer 178 and make electrical connection to conductive vias 184. Conductive layer 188 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. An electrically conductive layer 192 is formed over surface 128 of substrate 120. Conductive layer 192 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 192 operates as back-side drain contact for mSJMOS or MOSFET 196.

FIG. 4t is a cross-sectional view of MOSFET 196 illustrating n columns 172, p columns 170, insulating layer 176, and trench 158. In one embodiment, trench 158 has a width of 0.5 μm. The vapor phase deposition or plasma doping makes the formation of p columns 170 practical given the narrow trench width.

FIGS. 4s-4t illustrate two cells 198a and 198b of mSJMOS or MOSFET 196. MOSFET 196 is a multi-cell vertical power MOSFET having applications in DC-DC power converters, aerospace, and general purpose portable electrical devices. FIG. 5 is a top view of MOSFET 196 showing multiple cells 198 arranged in an x by y array. Cells 198 can be rectangular, circular, or other geometric shape. For one cell, n+source region 140 is the source of the MOSFET, N-epi device layer 136 and N+ bulk Si substrate 120 operates as the drain, polysilicon material 148 and insulating layer 146 is the gate structure, and the portion of p body 138 vertically along polysilicon material 148 is the channel between the source and drain. P column 170 and n column 172 form the super-junction structure, with a charge balance between the p column and n column, to support a high breakdown voltage for the MOSFET. MOSFET cells 198 are electrically connected in parallel to form a power MOSFET for high current carrying capacity. In one embodiment, MOSFET cells 198 have a pitch of 5.0 μm and density of 4.0 million cells/cm². The ability to form p columns 170 to a depth of 100 μm, with a trench width of say 0.5 μm, relies on the vapor phase deposition and diffusion to extend the dopant to the requisite depths in a narrow trench. The structure of MOSFET 196 has a feature size that is scalable to reduce cell size and provide a higher cell density, which increases the number of cells in the MOSFET and reduces RDS_{ON} less than 5.0 mohms-cm2 at maximum drain current I_{D} of 100.0 amperes. MOSFET 196 can be embodied on semiconductor die 104.

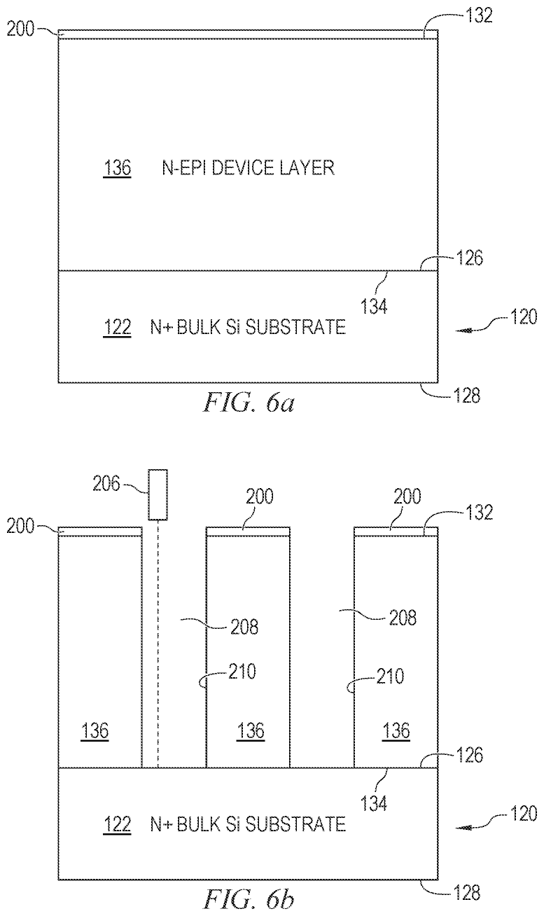

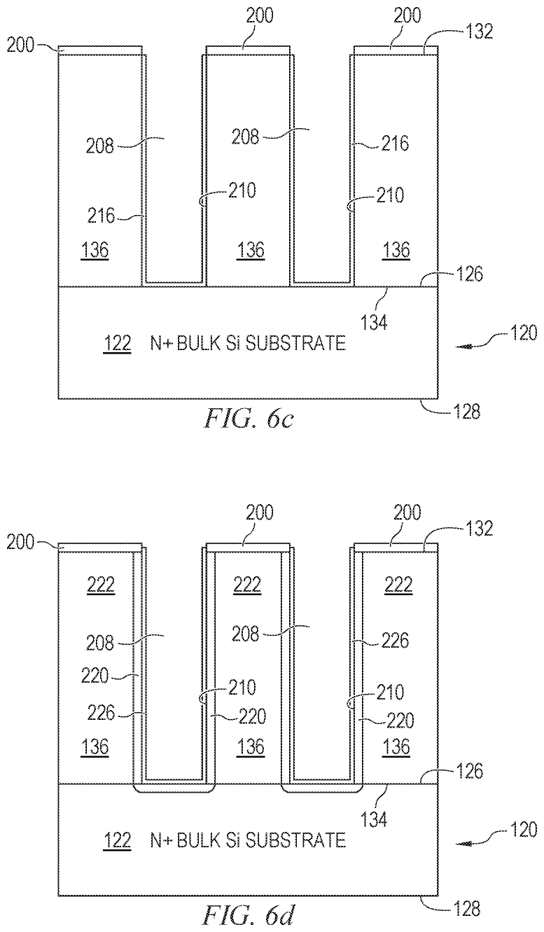

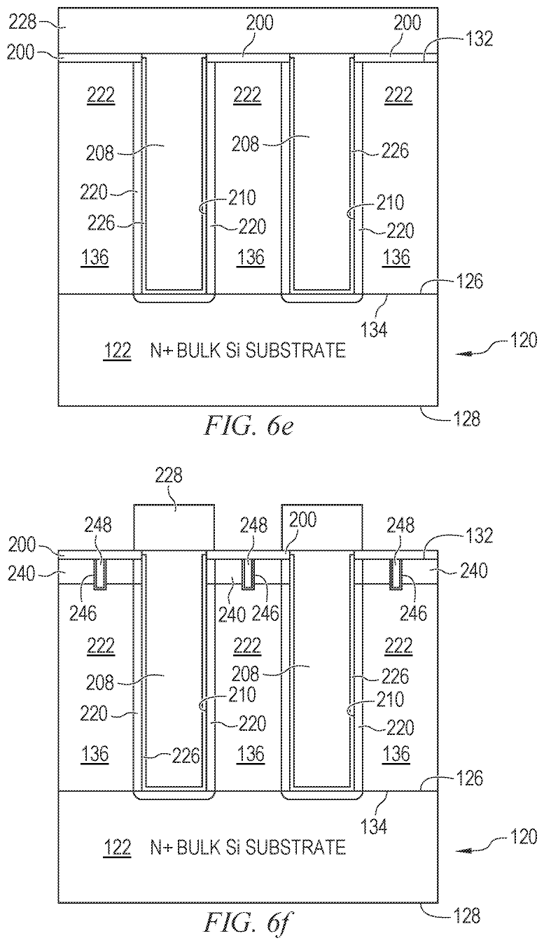

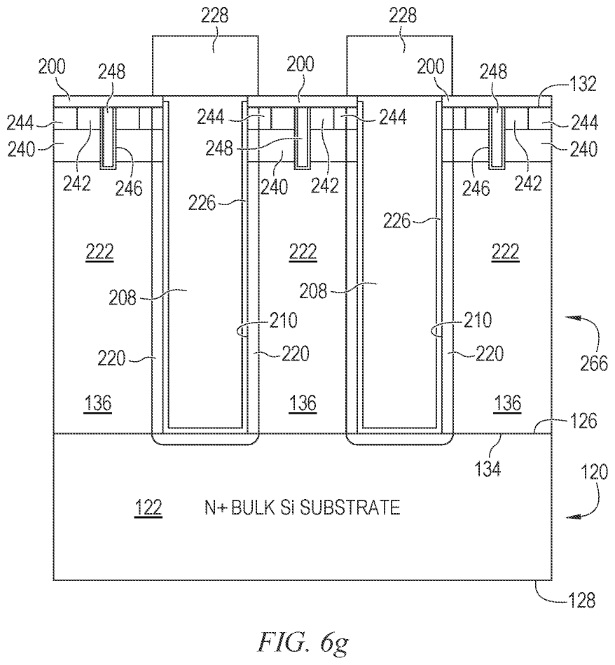

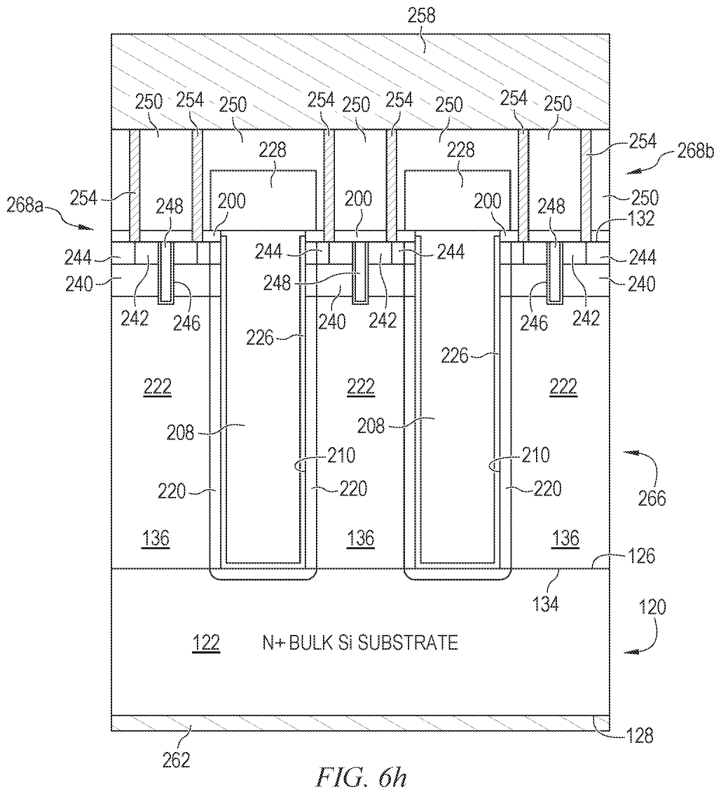

FIGS. 6a-6h illustrate another process of forming a multi-cell MEMS super-junction MOSFET using vapor phase deposition to optimize for R_{DSON}. Continuing from FIG. 4e, insulating layer 200 is formed over surface 132 of N-epi device layer 136, as shown in FIG. 6a. Insulating layer 200 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation.

In FIG. 6b, a portion of insulating layer 200 and N-epi device layer 136 is removed by a DRIE or LDA using laser 206 to form trench 208. Trench 208 includes substantially vertical side surfaces 210. Trench 208 must extend at least to surface 126, and in most cases, will extend past surface 126 into substrate material 122. In the case of trench etching, trenches 208 can be formed by DRIE, with a width and depth similar to trench 158, depending on epi thickness, to extend past surface 126 into substrate material 122. The width of trench 208 is made small to decrease cell pitch and increase cell density. The depth of trench 208 is greater for higher voltages and thicker epi. The DRIE is a highly anisotropic etch process used to create deep penetration, steep-sided holes, cavities, and trenches in wafers/substrates, typically with high aspect ratios. DRIE utilizes an ionized gas or plasma, such as SF₆, to remove material from N-epi device layer 136 and semiconductor material 122. DRIE technology permits deeper trenches 208 with straighter side surfaces 210. To create deep anisotropic etching of silicon, the etch process switches between different plasma chemistries to provide fluorine-based etching of the silicon while protecting the side surface of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 208. Alternatively, trenches 208 can be formed by plasma etching, RIE, sputter etching, vapor phase etching, and chemical etching. A first mask (not shown) is typically formed over surface 132 to isolate trenches 208 during the etching process.

The side surfaces 210 of each trench 208 can be smoothed using an isotropic plasma etch and may be used to remove a thin layer of silicon, e.g., 100-1000 A from the trench sidewalls. Alternatively, a sacrificial thermal oxide or silicon dioxide layer can be grown on sidewall surfaces 210 of trenches 208. The sacrificial thermal oxide is then removed using an etch, such as a buffered oxide etch, or a diluted HF acid etch, or other wet chemistry following by HF vapor phase fuming, to smooth the inner wall. Another sacrificial thermal oxide layer is again grown on side surfaces 210 of trenches 208. The sacrificial thermal oxide layer is again removed by wet chemistry following by HF vapor phase fuming to smooth the inner wall. The process of repetitive growth of thermal oxide and removal continues multiple times until side surface 210 of trench 208 is smooth. By eliminating the scalloping from the DRIE etch and using the sacrificial thermal oxide layer followed by HF fuming or any oxide and silicon etches, side surface 210 can be smoothed to a tapered form. The use of the smoothing technique can produce smooth trench surfaces with rounded corners while removing residual stress and unwanted contaminates.

In FIG. 6c, thin film 216 is deposited on side surfaces 210 of trenches 208 using low temperature vapor phase deposition or plasma doping. Thin film 216 contains p-type dopant, such as boron, aluminum, or gallium impurities. In one embodiment, p type thin film 216 is deposited by CVD, PVD, and/or PECVD. In FIG. 6d, p type thin film 216 is then diffused into N-epi device layer 136 by application of pressure and heat, e.g., in a reaction chamber, in the range of 800-1000° C. at atmospheric pressure. Alternatively, the impurity atoms are transported from the vapor source onto surface 210 of trench 208 and simultaneously diffused into the semiconductor wafer, again by application of heat and pressure in a reaction chamber. The vapor source maintains a constant level of surface concentration during the entire diffusion period. The diffusion forms p regions or columns 220, leaving n regions or columns 222 from N-epi device layer 136 between the p columns. That is, forming p column 220 retains a portion of N-epi device layer 136 as n column 222 adjacent to the p column. Accordingly, p columns 220 are formed by vapor phase deposition or plasma doping and diffusion, and n columns 222 are the remaining N-epi device layer 136 between the p columns. The vapor phase deposition or plasma doping and diffusion is particularly useful to form p columns 220, given the narrow trenches 208, e.g., 0.5 μm or less.

An insulating layer 226 is formed within trench 208 over side surface 210 of p columns 220. Insulating layer 226 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 226 typically, although not necessarily, covers the bottom of trench 208.

In FIG. 6e, insulating layer or material 228 is formed over insulating layer 200 and trench 208. Insulating material 228 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 228 is formed using a MEMS layer transfer or layer bonding process to form a cap over trench 208, as it is not necessary to completely fill the trenches with insulating material. Alternatively, insulating material 228 is formed within trench 208, similar to FIG. 4q. As part of MEMS layer transfer, insulating layer or cap 208, as an entire wafer, can be direct wafer bonded to insulating layer 200 to cover trench 208.

Insulating material 228 can also be formed to cap trenches 208 using other techniques, such as LPCVD, TEOS, or other suitable oxide deposition process. Insulating material 228 can be polysilicon, re-crystallized polysilicon, single crystal silicon, or SIPOS. In one embodiment, insulating material 228 is SIPOS deposited into trenches 208 using a SOG technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

In FIG. 6f, a portion of insulating material 228 is removed by an etching process or LDA to expose insulating layer 200 to allow formation of the p body, gate structure, and source region, while leaving insulating material 228 over trench 208. Surface 132 of N-epi device layer 136 is implanted with a p-type impurity, such as B, Al, or Ga, similar to FIG. 4f. The implant is performed at an energy level of about 30-200 KeV with a dose between 1e16 and 1e18 atoms/cm³, preferably 4e17 atoms/cm³. The p-type impurities are driven-in, at a temperature of 900° C. for 10-30 minutes, to form p body 240.

A portion of p body 240 and N-epi device layer 136 is removed by an etching process or LDA to form a trench extending into the N-epi device layer, similar to FIGS. 4i-4j. An insulating layer 246 is formed over the side surface within the trench. Insulating layer 246 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 246 is an oxide layer. Polysilicon material 248 is formed over insulating layer 246. Polysilicon material 248 can be formed by PVD, CVD, screen printing, spin coating, spray coating, or other suitable deposition process. Polysilicon material 248 operates as a gate field plate.

In FIG. 6g, surface 132 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form n+ source region 242, similar to FIG. 4g. Surface 132 is further implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form p+ contact 244.

In FIG. 6h, insulating layer 250 is formed over insulating layer 200 and insulating layer 228. Insulating layer 250 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 250 operates an ILD. A portion of insulating layer 250 is removed by an etching process or LDA to form vias through the insulating layer extending to n+ source region 242, similar to FIG. 4r. The vias are filled with conductive material to form conductive vias 254. Conductive vias 254 can be one or more layers of Al, Cu, Sn, Ni, Au, Ag, W, or other suitable electrically conductive material formed using patterning with PVD, CVD, sputtering, electrolytic plating, electroless plating process, or other suitable metal deposition process. Conductive vias 254 make electrical contact with n+ source region 242. Conductive vias 254 are also used to generate an electric field for polysilicon gate material 248 (not shown).

One or more electrically conductive layers 258 are formed over insulating layer 250 and make electrical connection to conductive vias 254, similar to FIG. 4t. Conductive layer 258 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. An electrically conductive layer 262 is formed over surface 128 of substrate 120. Conductive layer 262 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 262 operates as back-side drain contact for mSJMOS or MOSFET 266.

FIG. 6h illustrates two cells 268a and 268b of mSJMOS or MOSFET 266, similar to FIGS. 4s-4t. MOSFET 266 is a multi-cell vertical power MOSFET having applications in DC-DC power converters, aerospace, and general purpose portable electrical devices. A top view of MOSFET 266 showing multiple cells 268 arranged in an x by y array would be similar to FIG. 5. For one cell, n+ source region 242 is the source of the MOSFET, N-epi device layer 136 and N+ bulk Si substrate 120 operates as the drain, polysilicon material 248 and insulating layer 246 is the gate structure, and the portion of p body 138 vertically along polysilicon material 248 is the channel between the source and drain. P column 220 and n column 222 form the super-junction structure, with a charge balance between the p column and n column, to support a high breakdown voltage for the MOSFET. MOSFET cells 268 are electrically connected in parallel to form a power MOSFET for high current carrying capacity. In one embodiment, MOSFET cells 268 have a pitch of 5.0 μm and density of 4.0 million cells/cm². The ability to form p columns 220 to a depth of 100 μm, with a trench width of say 0.5 μm, relies on the vapor phase deposition and diffusion to extend the dopant to the requisite depths in a narrow trench. The structure of MOSFET 266 has a feature size that is scalable to reduce cell size and provide a higher cell density, which increases the number of cells in the MOSFET and reduces RDS_{ON} to 5.0 mohms-cm2 at maximum drain current I_{D} of 100.0 amperes. MOSFET 266 can be embodied on semiconductor die 104.

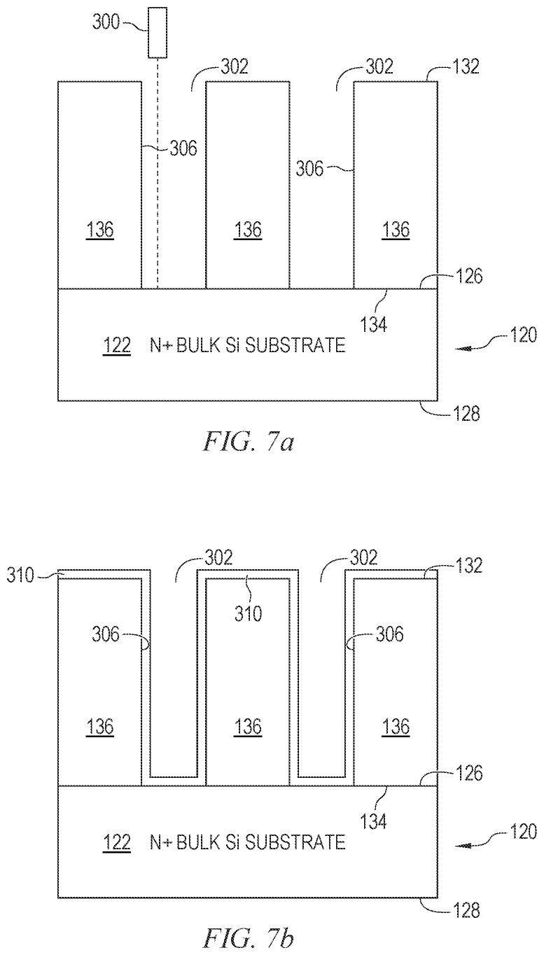

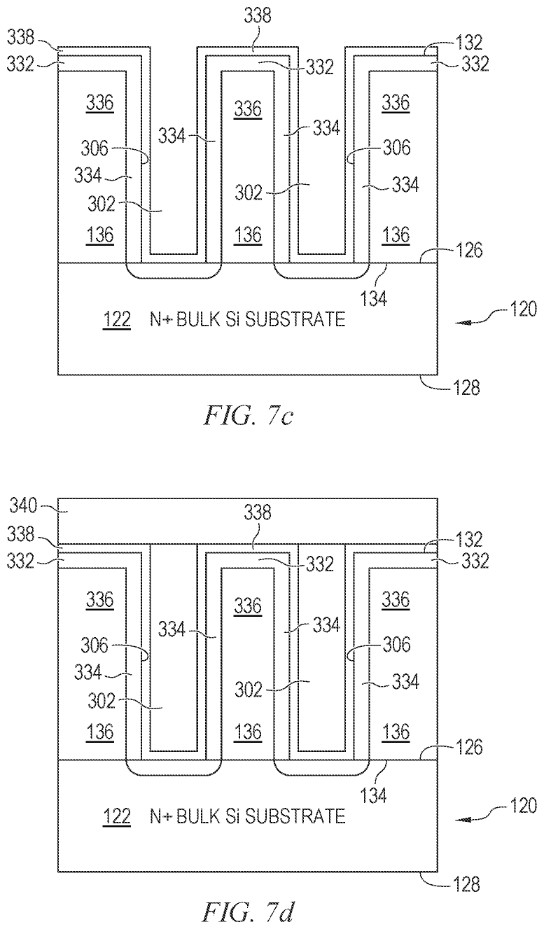

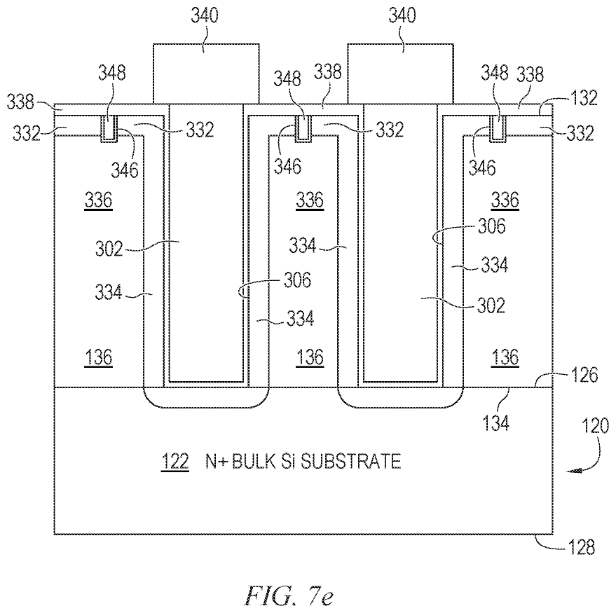

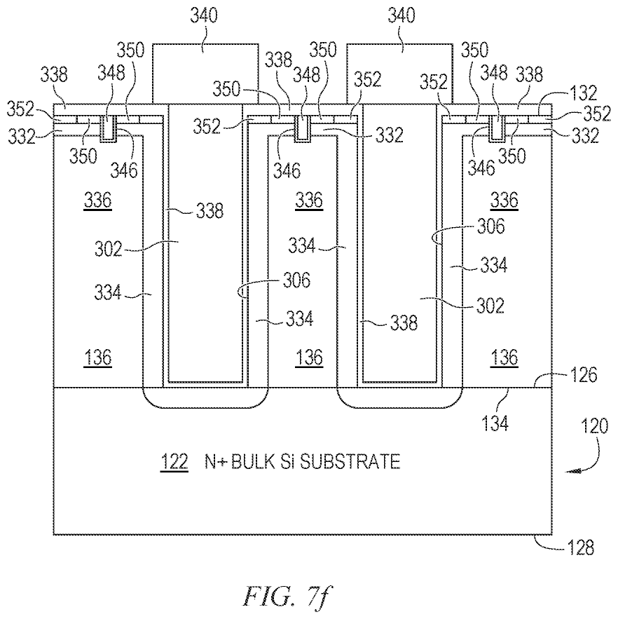

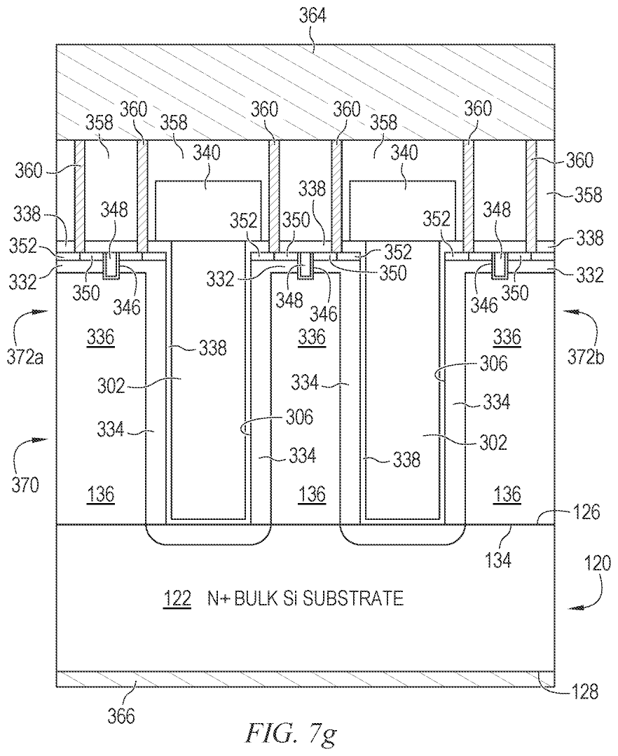

FIGS. 7a-7g illustrate another process of forming a multi-cell MEMS super-junction MOSFET using epi deposition or ALD to optimize for R_{DSON}. Continuing from FIG. 4e, a portion of N-epi device layer 136 is removed by a trench gate etching process or LDA using laser 300 to form trench 302, as shown in FIG. 7a. Trench 302 includes substantially vertical side surfaces 306. Trench 302 must extend at least to surface 126, and in most cases, will extend past surface 126 into substrate material 122. In the case of trench etching, trenches 302 can be formed by DRIE, with a width and depth similar to trench 158, depending on epi thickness, to extend past surface 126 into substrate material 122. The width of trench 302 is made small to decrease cell pitch and increase cell density. The depth of trench 302 is greater for higher voltages and thicker epi. The DRIE is a highly anisotropic etch process used to create deep penetration, steep-sided holes, cavities, and trenches in wafers/substrates, typically with high aspect ratios. DRIE utilizes an ionized gas or plasma, such as SF₆, to remove material from N-epi device layer 136 and semiconductor material 122. DRIE technology permits deeper trenches 302 with straighter side surfaces 306. To create deep anisotropic etching of silicon, the etch process switches between different plasma chemistries to provide fluorine-based etching of the silicon while protecting the side surface of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 302. Alternatively, trenches 302 can be formed by plasma etching, DRIE, sputter etching, vapor phase etching, and chemical etching. A first mask (not shown) is typically formed over surface 132 to isolate trenches 302 during the etching process.

The side surfaces 306 of each trench 302 can be smoothed using an isotropic plasma etch and may be used to remove a thin layer of silicon, e.g., 100-1000 A from the trench sidewalls. Alternatively, a sacrificial thermal oxide or silicon dioxide layer can be grown on sidewall surfaces 306 of trenches 302. The sacrificial thermal oxide is then removed using an etch, such as a buffered oxide etch, or a diluted HF acid etch, or other wet chemistry following by HF vapor phase fuming, to smooth the inner wall. Another sacrificial thermal oxide layer is again grown on side surfaces 306 of trenches 302. The sacrificial thermal oxide layer is again removed by wet chemistry following by HF vapor phase fuming to smooth the inner wall. The process of repetitive growth of thermal oxide and removal continues multiple times until side surface 306 of trench 302 is smooth. By eliminating the scalloping from the DRIE etch and using the sacrificial thermal oxide layer followed by HF fuming or any oxide and silicon etches, side surface 306 can be smoothed to a tapered form. The use of the smoothing technique can produce smooth trench surfaces with rounded corners while removing residual stress and unwanted contaminates.

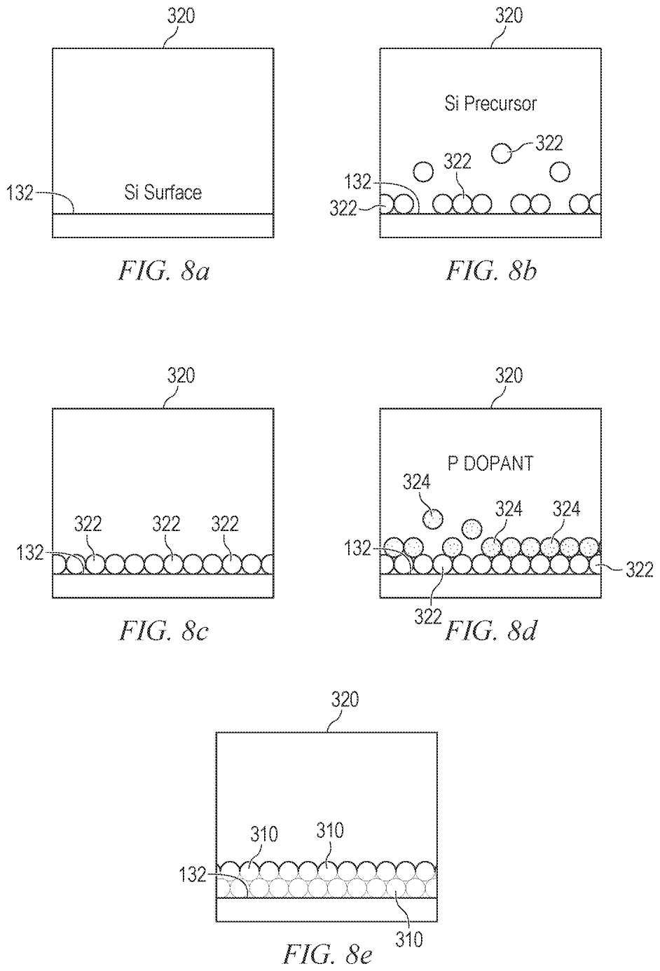

In FIG. 7b, epi layer 310 is epitaxially grown on surface 132 and side surfaces 306 of trenches 302. Alternatively, epi layer 310 is formed by atomic level deposition (ALD). An example of ALD is shown in FIGS. 8a-8e. FIG. 8a shows a semiconductor surface, such as surface 132 and 306, in reaction chamber 320. In FIG. 8b, precursors 322 flow into reaction chamber 320 is a gaseous state. FIG. 8c shows precursors 322 coating or absorbing into the target surface, i.e., surfaces 132 and 306. In FIG. 8d, a second gas with p type dopants 324 is introduced into reaction chamber 320 to react with precursors 322. FIG. 8e shows the resulting p type epi layer 310 formed on surfaces 132 and 306. ALD offers exceptional conformality on high-aspect ratio structures, thickness control at the angstrom level, and tunable film composition. Either by epitaxial growth or ALD, epi layer 310 contains p-type dopant, such as boron, aluminum, or gallium impurities.

In FIG. 7c, p type epi layer 310 is diffused into N-epi device layer 136 by application of pressure and heat, e.g., in a reaction chamber, in the range of 800-1000° C. at atmospheric pressure. Alternatively, the impurity atoms are transported from the vapor source onto side surface 306 of trench 302 and simultaneously diffused into the semiconductor wafer, again by application of heat and pressure in a reaction chamber. The vapor source maintains a constant level of surface concentration during the entire diffusion period. The diffusion of p type epi layer 310 into surface 132 forms p body regions 332. The diffusion of p type epi layer 310 into side surface 306 of trench 302 forms p regions or columns 334, leaving n regions or columns 336 from N-epi device layer 136 between the p columns. That is, forming p column 334 retains a portion of N-epi device layer 136 as n column 336 adjacent to the p column. Accordingly, p columns 334 are formed by epi growth and diffusion and n columns 336 are the remaining N-epi device layer 136 between the p columns. The epi layer deposition or ALD and diffusion is particularly useful to form p columns 334, given the narrow trenches 302, e.g., 0.5 μm or less.

An insulating layer 338 is formed over surface 132 and within trench 302 over side surface 306 of p columns 334. Insulating layer 338 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 338 typically, although not necessarily, covers the bottom of trench 302.

In FIG. 7d, insulating layer or material 340 is formed over insulating layer 338 and trench 302. Insulating material 340 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 340 is formed using a MEMS layer transfer or layer bonding process to form a cap over trench 302, as it is not necessary to completely fill the trenches with insulating material. Alternatively, insulating material 340 is formed within trench 302, similar to FIG. 4q. As part of MEMS layer transfer, insulating layer or cap 340, as an entire wafer, can be direct wafer bonded to insulating layer 338 to cover trench 302.

Insulating material 340 can also be formed to cap trenches 302 using other techniques, such as LPCVD, TEOS, or other suitable oxide deposition process. Insulating material 340 can be polysilicon, re-crystallized polysilicon, single crystal silicon, or SIPOS. In one embodiment, insulating material 340 is SIPOS deposited into trenches 302 using a SOG technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

In FIG. 7e, a portion of insulating material 340 is removed by an etching process or LDA to expose insulating layer 338 to allow formation of the gate structure and source region, while leaving insulating material 340 over trench 302. A portion of p body 332 and N-epi device layer 136 is removed by an etching process or LDA to form a trench extending into the N-epi device layer, similar to FIGS. 4i-4j. An insulating layer 346 is formed over the side surface within the trench. Insulating layer 346 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 346 is an oxide layer. Polysilicon material 348 is formed over insulating layer 346. Polysilicon material 348 can be formed by PVD, CVD, screen printing, spin coating, spray coating, or other suitable deposition process. Polysilicon material 348 operates as a gate field plate.

In FIG. 7f, surface 132 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form n+ source region 350, similar to FIG. 4g. Surface 132 is further implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form p+ contact 352.

In FIG. 7g, insulating layer 358 is formed over insulating layer 338 and insulating layer 340. Insulating layer 358 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 358 operates an ILD. Insulating layer 358 can extend over insulating layer 340. A portion of insulating layer 358 is removed by an etching process or LDA to form vias through the insulating layer extending to n+ source region 350, similar to FIG. 4r. The vias are filled with conductive material to form conductive vias 360. Conductive vias 360 can be one or more layers of Al, Cu, Sn, Ni, Au, Ag, W, or other suitable electrically conductive material formed using patterning with PVD, CVD, sputtering, electrolytic plating, electroless plating process, or other suitable metal deposition process. Conductive vias 360 make electrical contact with n+ source region 350. Conductive vias 360 are also used to generate an electric field for polysilicon gate material 348 (not shown).

One or more electrically conductive layers 364 are formed over insulating layer 358 and make electrical connection to conductive vias 360, similar to FIG. 4t. Conductive layer 364 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. An electrically conductive layer 366 is formed over surface 128 of substrate 120. Conductive layer 366 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 366 operates as back-side drain contact for mSJMOS or MOSFET 370.

FIG. 7g illustrates two cells 372a and 372b of mSJMOS or MOSFET 370, similar to FIGS. 4s-4t. MOSFET 370 is a multi-cell vertical power MOSFET having applications in DC-DC power converters, aerospace, and general purpose portable electrical devices. A top view of MOSFET 370 showing multiple cells 372 arranged in an x by y array would be similar to FIG. 5. For one cell, n+ source region 350 is the source of the MOSFET, N-epi device layer 136 and N+ bulk Si substrate 120 operates as the drain, polysilicon material 348 and insulating layer 346 is the gate structure, and the portion of p body 332 vertically along polysilicon material 348 is the channel between the source and drain. P column 334 and n column 336 form the super-junction structure, with a charge balance between the p column and n column, to support a high breakdown voltage for the MOSFET. MOSFET cells 370 are electrically connected in parallel to form a power MOSFET for high current carrying capacity. In one embodiment, MOSFET cells 370 have a pitch of 5.0 μm and density of 4.0 million cells/cm². The ability to form p columns 334 to a depth of 100 μm, with a trench width of say 0.5 μm, relies on the epi doping and diffusion to extend the dopant to the requisite depths in a narrow trench. The structure of MOSFET 370 has a feature size that is scalable to reduce cell size and provide a higher cell density, which increases the number of cells in the MOSFET and reduces RDS_{ON} to 5.0 mohms-cm2 at maximum drain current I_{D} of 100.0 amperes. MOSFET 370 can be embodied on semiconductor die 104.

While one or more embodiments of the present invention have been illustrated in detail, the skilled artisan will appreciate that modifications and adaptations to those embodiments may be made without departing from the scope of the present invention as set forth in the following claims.

1. A method of making a semiconductor device, comprising:
providing a substrate;
forming a semiconductor layer having a first conductivity type over the substrate;
forming a trench through the semiconductor layer;
forming an epitaxial layer having a second conductivity type opposite the first conductivity type over a surface of the semiconductor layer and a side surface of the trench; and
diffusing the epitaxial layer into the semiconductor layer to form a first column of semiconductor material having the second conductivity type within the semiconductor layer.

2. The method of claim 1, further including retaining a portion of the semiconductor layer as a second column of semiconductor material having the first conductivity type adjacent to the first column of semiconductor material.

3. The method of claim 1, further including:
forming a first insulating layer over the side surface of the trench;
forming a body region within the semiconductor layer from the epitaxial layer diffused into the semiconductor layer;
forming a source region within the body region; and
forming a gate region within the body region.

4. The method of claim 3, further including:
forming a second insulating layer over the trench;
forming a third insulating layer over the second insulating layer;
forming a conductive via through the third insulating layer to the source region; and
forming a conductive layer over the third insulating layer in electrical contact with the conductive via.

5. The method of claim 4, further including forming the second insulating layer over the trench by direct wafer bonding.

6. The method of claim 1, further including forming the semiconductor layer over the substrate by direct wafer bonding.

7. A method of making a semiconductor device, comprising:
providing a substrate;
forming a semiconductor layer over the substrate;
forming a trench through the semiconductor layer;
forming an epitaxial layer over a surface of the semiconductor layer and a side surface of the trench; and
diffusing the epitaxial layer into the semiconductor layer to form a first column of semiconductor material within the semiconductor layer.

8. The method of claim 7, wherein the semiconductor layer has a first conductivity type and diffusing the epitaxial layer forms a first column of semiconductor material having a second conductivity type opposite the first conductivity type with a remaining portion of the semiconductor layer providing a second column of semiconductor material having the first conductivity type adjacent to the first column of semiconductor material.

9. The method of claim 7, further including:
forming a first insulating layer over the side surface of the trench;
forming a body region within the semiconductor layer from the epitaxial layer diffused into the semiconductor layer;
forming a source region within the body region; and
forming a gate region within the body region.

10. The method of claim 9, further including:
forming a second insulating layer over the trench;
forming a third insulating layer over the second insulating layer;
forming a conductive via through the third insulating layer to the source region; and
forming a conductive layer over the third insulating layer in electrical contact with the conductive via.

11. The method of claim 10, further including forming the second insulating layer over the trench by direct wafer bonding.

12. The method of claim 7, further including forming the semiconductor layer over the substrate by direct wafer bonding.

13. The method of claim 7, wherein the trench is 0.5 micrometers or less in width.

14. A semiconductor device, comprising:
a substrate;
a semiconductor layer formed over the substrate;
a trench formed through the semiconductor layer; and
an epitaxial layer formed over a surface of the semiconductor layer and a side surface of the trench and diffused into the semiconductor layer.

15. The semiconductor device of claim 14, wherein the semiconductor layer has a first conductivity type and diffusing the epitaxial layer forms a first column of semiconductor material having a second conductivity type opposite the first conductivity type within the semiconductor layer with a remaining portion of the semiconductor layer providing a second column of semiconductor material having the first conductivity type adjacent to the first column of semiconductor material.

16. The semiconductor device of claim 14, further including:
a first insulating layer formed over the side surface of the trench;
a body region formed within the semiconductor layer from the epitaxial layer diffused into the semiconductor layer;
a source region formed within the body region; and
a gate region formed within the body region.

17. The semiconductor device of claim 16, further including:
a second insulating layer formed over the trench;
a third insulating layer formed over the second insulating layer;
a conductive via formed through the third insulating layer to the source region; and
a conductive layer formed over the third insulating layer in electrical contact with the conductive via.

18. The semiconductor device of claim 14, wherein the trench extends to the substrate.

19. The semiconductor device of claim 14, further including the semiconductor layer is formed over the substrate by direct wafer bonding.

20. The semiconductor device of claim 14, wherein the trench is 0.5 micrometers or less in width.

21. The method of claim 14, wherein the semiconductor layer is doped using atomic layer deposition.

22. The method of claim 1, further including doping the semiconductor layer over the substrate using atomic layer deposition.

23. The method of claim 7, further including doping the semiconductor layer over the substrate using atomic layer deposition.

24. A method of making a semiconductor device, comprising:
providing a substrate;
forming a semiconductor layer over the substrate;
forming a trench through the semiconductor layer;
forming an epitaxial layer over a surface of the semiconductor layer and a side surface of the trench using atomic layer deposition; and
diffusing the epitaxial layer into the semiconductor layer to form a first column of semiconductor material within the semiconductor layer.

25. The method of claim 24, wherein the semiconductor layer has a first conductivity type and diffusing the epitaxial layer forms a first column of semiconductor material having a second conductivity type opposite the first conductivity type with a remaining portion of the semiconductor layer providing a second column of semiconductor material having the first conductivity type adjacent to the first column of semiconductor material.

26. The method of claim 24, further including:
forming a first insulating layer over the side surface of the trench;
forming a body region within the semiconductor layer from the epitaxial layer diffused into the semiconductor layer;
forming a source region within the body region; and
forming a gate region within the body region.

27. The method of claim 26, further including:
forming a second insulating layer over the trench;
forming a third insulating layer over the second insulating layer;
forming a conductive via through the third insulating layer to the source region; and
forming a conductive layer over the third insulating layer in electrical contact with the conductive via.

28. The method of claim 27, further including forming the second insulating layer over the trench by direct wafer bonding.

29. The method of claim 24, further including forming the semiconductor layer over the substrate by direct wafer bonding.

30. The method of claim 24, wherein the trench is 0.5 micrometers or less in width.
